(19) United States
(12) Patent Application Publication
(10) Pub. No.: US 2017/0241271 A1
(43) Pub. Date: Aug. 24, 2017

(54) COMPONENT OF A MOLYBDENUM ALLOY AND METHOD FOR FORMING AN OXIDATION PROTECTION LAYER THEREFOR

(71) Applicant: MTU Aero Engines AG, Munich (DE)

(72) Inventors: Markus FRIED, Valley (DE); Wilfried SMARSLY, Munich (DE); Andreas BROETZNER, Vierkirchen (DE)

(21) Appl. No.: 15/431,925

(22) Filed: Feb. 14, 2017

(30) Foreign Application Priority Data
Feb. 24, 2016 (DE) 102016202872.3

(51) Int. Cl. F01D 5/28; C22C 30/00; C23C 14/16; F01D 9/02; C23C 14/58; C23C 16/42; C23C 16/38; C23C 16/56; C22C 27/04; C23C 14/34

(52) U.S. Cl. CPC F01D 5/28; C22C 27/04; C22C 30/00; C23C 14/165; C23C 14/34; C23C 14/5806; C23C 14/5853; C23C 16/42; C23C 16/38; C23C 16/56; F01D 9/02; F05D 2220/323; F05D 2230/313; F05D 2230/314; F05D 2230/40; F05D 2300/131

(57) ABSTRACT

Disclosed is a method for improving the high-temperature stability of a component, in particular a blade of a turbomachine, formed at least partially from a molybdenum alloy that, besides molybdenum, silicon, boron and titanium, comprises iron and/or yttrium. The method comprises depositing a diffusion barrier layer formed from technically pure molybdenum or tungsten or being an alloy based on molybdenum and/or tungsten at least on an outer surface, which comprises the molybdenum alloy, of the component, and depositing silicon on the diffusion barrier layer to form molybdenum silicides and/or tungsten silicides.

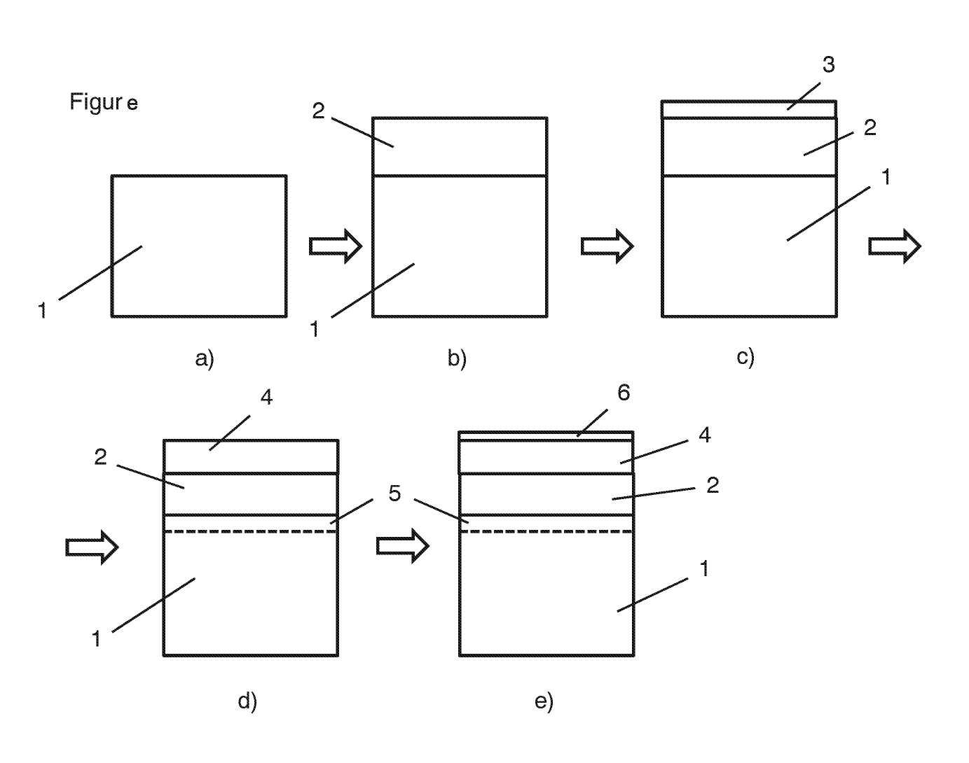

### CROSS-REFERENCE TO RELATED APPLICATIONS

The present application claims priority under 35 U.S.C. §119 of German Patent Application No. 102016202872.3, filed Feb. 24, 2016, the entire disclosure of which is expressly incorporated by reference herein.

### BACKGROUND OF THE INVENTION

1. Field of the Invention

The present invention relates to a component of a molybdenum alloy that comprises silicon, boron and titanium and one or both of iron and yttrium, in particular a blade of a turbomachine such as an aircraft engine, and to a method for improving the high-temperature stability of such a component.

2. Discussion of Background Information

Molybdenum alloys having proportions of silicon and boron as well as further alloy elements, which form intermetallic phases such as silicides, are advantageous for use in high-temperature environments as they have melting temperatures of above 2000° C. as well as a sufficient structural strength. Because of the suitable mechanical properties at high temperatures, such materials are also advantageous for use in turbomachines, such as static gas turbines or aircraft engines, for example as blade materials, since in that case it is necessary at least partially to use materials which have high strengths at high temperatures and under high mechanical loads, for example a high creep strength. At the same time, however, it is also necessary for such materials to have a certain high-temperature stability in order to be able to ensure a sufficient lifetime of the components.

In the case of the molybdenum alloys mentioned above, however, there is still a need for improvement in respect of the oxidation resistance. Although there are already proposals in the prior art to improve the oxidation resistance of molybdenum-based alloys, inadequacies are still found easily for highly alloyed molybdenum alloys having a plurality of alloy elements.

For example, U.S. Pat. No. 7,005,191, the entire disclosure of which is incorporated by reference herein, proposes, for ternary molybdenum alloys consisting of molybdenum, silicon and boron, to deposit silicon on the surface of a corresponding component by chemical vapor deposition so that a silicon-rich silicide layer of MoSi₂ is formed. During oxidation of the silicon-rich silicide layer, the formation of a slowly growing silicon dioxide layer takes place, which functions as oxidation protection, as well as the formation of the Mo₅SiB₂ phase, which acts as a diffusion barrier layer, at the interface of the silicide layer with the substrate made of the Mo—Si—B alloy.

This is also described in U.S. Pat. No. 6,340,398, the entire disclosure of which is incorporated by reference herein, for substrates made of molybdenum alloys comprising at least 50% molybdenum. For materials which do not have enough molybdenum to form molybdenum disilicide in the surface region, for example metals such as copper or nickel or alloys thereof, in order to form a corresponding protective layer based on silicon dioxide it is proposed initially to apply a molybdenum layer, so that a silicide layer that provides the silicon for the silicon oxide layer formation can in turn be formed by the subsequent deposition of silicone.

Although this procedure, as described in U.S. Pat. No. 7,005,191 for ternary Mo—Si—B alloys provides good results, it has been found that oxidation protection by silicon enrichment of the surface and subsequent oxidation is insufficient for more highly alloyed molybdenum alloys, i.e. for quaternary molybdenum alloys or molybdenum alloys having more than four alloy elements, which are optimized with regard to their mechanical properties, density and high-temperature properties.

In view of the foregoing, it would be advantageous to have available a method for improving the high-temperature stability of highly alloyed molybdenum alloys that, besides molybdenum, silicon, boron and titanium, contain at least iron and/or yttrium, as well as correspondingly produced components. It would also be advantageous if at the same time, it would be possible to apply the corresponding method for improving the high-temperature stability simply and reliably, and if correspondingly produced components would be usable securely, reliably and for a long time, particularly as blades in turbomachines, and in particular aircraft engines.

### SUMMARY OF THE INVENTION

The present invention provides a method for improving the high-temperature stability of a component which is formed at least partially from a molybdenum alloy that, besides molybdenum, silicon, boron and titanium, comprises iron and/or yttrium. The method comprises depositing at least on an outer surface, which comprises the molybdenum alloy, of the component a diffusion barrier layer formed from technically pure molybdenum or technically pure tungsten or being an alloy based on molybdenum and/or tungsten, and depositing silicon on the diffusion barrier layer after deposition of the diffusion barrier layer to form molybdenum silicides and/or tungsten silicides.

In one aspect of the method, the component may be a blade of a turbomachine and/or the alloy based on molybdenum and/or tungsten may comprise niobium and/or tantalum.

In another aspect of the method, boron may be deposited with the silicon in order to form molybdenum boride and/or tungsten boride and/or molybdenum borosilicides and/or tungsten borosilicides.

In yet another aspect, the deposition of the diffusion barrier layer may be carried out by physical vapor deposition, for example, by sputtering and/or the deposition of the silicon may be carried out by chemical vapor deposition.

In a still further aspect, the method may further comprise carrying out a heat treatment to form the molybdenum silicides and/or tungsten silicides after deposition of the silicon and/or may further comprise carrying out a heat treatment in an atmosphere containing oxygen after formation of the molybdenum silicides and/or tungsten silicides, in order to form an oxide layer.

In another aspect, the diffusion barrier layer may comprise at least 90 wt % of molybdenum and/or the diffusion barrier layer may comprise no tungsten.

In another aspect, the diffusion barrier layer may comprise no molybdenum or may comprise both molybdenum and tungsten.

The present invention also provides a component for high-temperature applications. The component, which may have been produced by the method set forth above, is formed at least partially from a molybdenum alloy that, besides molybdenum, silicon, boron and titanium, comprises iron and/or yttrium. A diffusion barrier layer formed from technically pure molybdenum or tungsten or being an alloy based on molybdenum and/or tungsten is arranged at least on a region, which comprises the molybdenum alloy, of the component. Further, a layer which comprises molybdenum silicides and/or tungsten silicides is present on the diffusion barrier layer.

In one aspect of the component, an oxide layer may be arranged on the layer comprising molybdenum silicides and/or tungsten silicides.

In another aspect, the component may be a component of a turbomachine, e.g., a guide vane or rotor blade thereof.

It has been found that there is a lattice structure in highly alloyed molybdenum alloys comprising silicon, boron, titanium and at least iron and/or yttrium besides the main alloy constituent molybdenum, so that in the event of silicon enrichment on the surface of a component produced from such molybdenum alloys and subsequent oxidation, constituents of the molybdenum alloy, for example titanium, diffuse outward and likewise form oxides there, although ones which hinder oxidation protection by a slowly growing silicon dioxide layer.

As a remedy, it is proposed to deposit a molybdenum layer or tungsten layer, or a molybdenum-rich or tungsten-rich layer, on the substrate of a molybdenum alloy comprising molybdenum, silicon, boron, titanium and at least iron and/or yttrium, since it has been found that this can act as a diffusion barrier layer so as to prevent components of the molybdenum alloy from diffusing outward and hindering the formation of a slowly growing compact silicon dioxide layer. Besides pure molybdenum layers or tungsten layers, it is also possible to provide mixed layers of molybdenum and tungsten, or molybdenum-rich or tungsten-rich layers in which by far the major part, i.e. for example more than about 75 wt %, e.g., more than about 90 wt %, is formed by molybdenum or tungsten. Niobium and/or tantalum may be alloyed into the molybdenum-rich or tungsten-rich diffusion barrier layer in order to match the thermal expansion coefficient of the diffusion barrier layer to the thermal expansion coefficient of the substrate. Furthermore, it is also possible to substitute molybdenum with tungsten and vice versa, so that alloys comprising molybdenum, tungsten, tantalum and/or niobium may also be envisaged for use as a diffusion barrier layer.

The diffusion barrier layer may, for example, be deposited by physical vapor deposition, and in particular by sputtering.

On the diffusion barrier layer of molybdenum and/or tungsten, or molybdenum-rich and/or tungsten-rich alloys, silicon may be deposited in order to form molybdenum silicides and/or tungsten silicides (MoSi₂, Mo₃Si, Mo₅Si₃, WSi₂, W₅Si₃), which provide silicon for subsequent oxidation to form a slowly growing silicon dioxide layer. At the same time, boron may be deposited with the silicon so that molybdenum and/or tungsten borides (MoB, WB) and/or molybdenum borosilicides and/or tungsten borosilicides (Mo₅Si₃(B), W₅Si₃(B), Mo₅SiB₂, W₅SiB₂) may additionally be formed in the silicide layer comprising molybdenum silicides and/or tungsten silicides. By adding boron into the silicide layer, the susceptibility of a corresponding layer structure to cracking is reduced. The silicon, or the silicon with proportions of boron, may, for example, be deposited by chemical vapor deposition.

In the event of a heat treatment taking place in addition to and/or simultaneously with deposition of silicon and/or boron, the above-described molybdenum silicides and/or tungsten silicides may be formed after and/or during the deposition of the silicon and/or boron, so that after this method step there is a silicide layer of molybdenum silicides and/or tungsten silicides and optionally molybdenum and/or tungsten borides as well as molybdenum borosilicides an/or tungsten borosilicides on the diffusion barrier layer of molybdenum and/or tungsten, or corresponding molybdenum-rich and/or tungsten-rich alloys. The component therefore already has a corresponding oxidation protection coating and may be used correspondingly, since during first use at high temperatures in an atmosphere containing oxygen a silicon dioxide layer that prevents further oxidation is automatically formed by the high proportion of silicon in the silicide layer.

The component may, however, also already be provided with a corresponding oxide layer before first use, by carrying out a heat treatment in an atmosphere containing oxygen so that a corresponding oxide layer can be formed. If there is boron in the silicide layer, then boron oxide may also be formed besides silicon oxide, or a borosilicate layer may be formed.

Exemplary alloy compositions which may be used for components according to the invention are specified in the table below (data respectively in at. %):

| Molyb- | | | | | | |
|---|---|---|---|---|---|---|
| denum | Silicon | Boron | Titanium | Iron | Yttrium | Zirconium |
| 46.5 | 12.5 | 8.5 | 27.5 | 2.0 | 2.0 | 1.0 |
| 49.5 | 12.5 | 8.5 | 27.5 | 0 | 2.0 | 0 |
| 49.5 | 12.5 | 8.5 | 27.5 | 2.0 | 0 | 0 |
| 48.5 | 13.5 | 8.5 | 26.5 | 2.0 | 0 | 1.0 |
| 51 | 12.5 | 8.5 | 25.0 | 2.0 | 0 | 1.0 |

### BRIEF DESCRIPTION OF THE DRAWING

The appended drawing (FIGURE) purely schematically an in a non-limiting manner shows the method sequence during the coating of a substrate made of an Mo—Si—B—Ti—Fe alloy.

### DETAILED DESCRIPTION OF EMBODIMENT OF THE INVENTION

The particulars shown herein are by way of example and for purposes of illustrative discussion of the embodiments of the present invention only and are presented in the cause of providing what is believed to be the most useful and readily understood description of the principles and conceptual aspects of the present invention. In this regard, no attempt is made to show details of the present invention in more detail than is necessary for the fundamental understanding of the present invention, the description in combination with the drawing making apparent to those of skill in the art how the several forms of the present invention may be embodied in practice.

The appended FIGURE shows in the subfigures a) to e) the method steps during the application of an oxidation protection layer according to the invention onto a substrate of a highly alloyed Mo—Si—B—Ti—Fe alloy comprising molybdenum, silicon, boron, Ti and iron as alloy constituents, the proportion of the alloy elements decreasing in the order of the list. As a molybdenum alloy, the main constituent molybdenum is present in the greatest proportion.

In substep a), a substrate 1 which is formed from an Mo—Si—B—Ti—Fe alloy is provided. A diffusion barrier layer 2 is deposited by means of sputtering on a surface of the substrate 1, the diffusion barrier layer 2 being formed from a molybdenum alloy which has small amounts of tantalum and/or niobium alloyed with it so as to match the thermal expansion coefficient to that of the substrate. In particular, the molybdenum alloy for the diffusion barrier layer may be an alloy in which the proportion of molybdenum is ≧90 wt %. The molybdenum may also be fully or partially replaced with tungsten.

After the deposition of the diffusion barrier layer 2 in substep b), silicon with a small proportion of boron is deposited by means of chemical vapor deposition in substep c) so that a silicon layer 3 with boron doping is formed on the diffusion barrier layer 2. At the same time, diffusion of silicon into the diffusion barrier layer 2 or diffusion of molybdenum out into the applied silicon layer 3 may occur by the effect of temperature during the chemical vapor deposition, so that a silicide layer 4 is formed. This is reinforced in process step d) by carrying out a heat treatment of the substrate with the layers 2, 3 applied thereon, so that all of the applied silicon with the corresponding proportion of boron is contained in the silicide layer 4, which comprises molybdenum silicides, molybdenum borides and molybdenum borosilicides, for example MoSi₂, MoB, Mo₅SiB₂. By the effective temperature during the heat treatment, a diffusion zone 5 is furthermore formed between the substrate 1 and the diffusion barrier layer 2, but without diffusion of elements from the substrate 1 into the outer region of the coating having taken place.

The correspondingly produced component may already be used after process step d), since in a high-temperature application in an atmosphere containing oxygen the silicide layer 4 provides silicon for the formation of a silicon oxide layer 6. By the formation of an oxide layer 6 from slowly growing silicon dioxide, an oxidation protection effect is provided for the correspondingly coated component. Because of the boron in the form of borides or borosilicides contained in the silicide layer 4, there may also be boron oxides or silicon borosilicate in the oxide layer 6.

Although the invention has been described clearly with the aid of the exemplary embodiment, it is clear to the person skilled in the art that the invention is not restricted to this exemplary embodiment but rather that variants are possible in that individual features may be omitted or other types of combinations of features may be implemented, so long as the protective scope of the appended claims is not departed from.

### LIST OF REFERENCE NUMERALS

1 substrate
2 diffusion barrier layer of Mo and/or W, or molybdenum-rich and/or tungsten-rich alloys
3 silicon layer
4 silicide layer
5 diffusion zone
6 oxide layer

What is claimed is:

1. A method for improving the high-temperature stability of a component which is formed at least partially from a molybdenum alloy that, besides molybdenum, silicon, boron and titanium, comprises iron and/or yttrium, wherein the method comprises depositing at least on an outer surface, which comprises the molybdenum alloy, of the component a diffusion barrier layer formed from technically pure molybdenum or tungsten or being an alloy based on molybdenum and/or tungsten, and depositing silicon on the diffusion barrier layer after deposition of the diffusion barrier layer to form molybdenum silicides and/or tungsten silicides.

2. The method of claim 1, wherein the component is a blade of a turbomachine.

3. The method of claim 1, wherein the alloy based on molybdenum and/or tungsten comprises niobium and/or tantalum.

4. The method of claim 1, wherein boron is deposited with the silicon in order to form molybdenum boride and/or tungsten boride and/or molybdenum borosilicides and/or tungsten borosilicides.

5. The method of claim 3, wherein boron is deposited with the silicon to form molybdenum boride and/or tungsten boride and/or molybdenum borosilicides and/or tungsten borosilicides.

6. The method of claim 1, wherein the deposition of the diffusion barrier layer is carried out by physical vapor deposition.

7. The method of claim 7, wherein the deposition of the diffusion barrier layer is carried out by sputtering.

8. The method of claim 1, wherein the deposition of the silicon is carried out by chemical vapor deposition.

9. The method of claim 1, wherein the method further comprises carrying out a heat treatment to form the molybdenum silicides and/or tungsten silicides after deposition of the silicon.

10. The method of claim 1, wherein the method further comprises carrying out a heat treatment in an atmosphere containing oxygen after formation of the molybdenum silicides and/or tungsten silicides, to form an oxide layer.

11. The method of claim 9, wherein the method further comprises carrying out a heat treatment in an atmosphere containing oxygen after formation of the molybdenum silicides and/or tungsten silicides, to form an oxide layer.

12. The method of claim 1, wherein the diffusion barrier layer comprises at least 90 wt % of molybdenum.

13. The method of claim 1, wherein the diffusion barrier layer comprises no tungsten.

14. The method of claim 1, wherein the diffusion barrier layer comprises no molybdenum.

15. The method of claim 1, wherein the diffusion barrier layer comprises both molybdenum and tungsten.

16. The method of claim 1, wherein the diffusion barrier layer is formed from technically pure molybdenum or tungsten

17. A component for high-temperature applications, wherein the component is formed at least partially from a molybdenum alloy that, besides molybdenum, silicon, boron and titanium, comprises iron and/or yttrium, wherein a diffusion barrier layer formed from technically pure molybdenum or tungsten or being an alloy based on molybdenum and/or tungsten is arranged at least on a region, which comprises the molybdenum alloy, of the component, and wherein a layer which comprises molybdenum silicides and/or tungsten silicides is arranged on the diffusion barrier layer.

18. The component of claim 17, wherein an oxide layer is arranged on the layer comprising molybdenum silicides and/or tungsten silicides.

19. The component of claim 17, wherein the component is a component of a turbomachine.

20. The component of claim 17, wherein the component is a guide vane or rotor blade of a turbomachine.
